(19) United States
(12) Patent Application Publication
(10) Pub. No.: US 2007/0187729 A1
(43) Pub. Date: Aug. 16, 2007

(54) Unipolar nanotube and field effect transistor having the same

(75) Inventors: Wan-jun Park, Seoul (KR); Noe-jung Park, Suwon-si (KR)

Correspondence Address: HARNESS, DICKEY & PIERCE, P.L.C., P.O. BOX 8910, RESTON, VA, 20195, US

(73) Assignee: Samsung Electronics Co. Ltd.

(21) Appl. No.: 11/585,085

(22) Filed: Oct. 24, 2006

(30) Foreign Application Priority Data
Feb. 16, 2006 (KR) 10-2006-0015153

(51) Int. Cl. H01L 29/76; D01F 9/12

(52) U.S. Cl. 257/288; 423/447.2; 977/938

(57) ABSTRACT

Example embodiments relate to a unipolar carbon nanotube having a carrier-trapping material and a unipolar field effect transistor having the unipolar carbon nanotube. The carrier-trapping material, which is sealed in the carbon nanotube, may readily transform an ambipolar characteristic of the carbon nanotube into a unipolar characteristic by doping the carbon nanotube. Also, p-type and n-type carbon nanotubes and field effect transistors may be realized according to the carrier-trapping material.

### PRIORITY STATEMENT

This application claims the benefit of priority under 35 U.S.C. § 119 from Korean Patent Application No. 10-2006-0015153, filed on Feb. 16, 2006 in the Korean Intellectual Property Office, the disclosure of which is incorporated herein in its entirety by reference.

### BACKGROUND OF THE INVENTION

1. Field of the Invention

Example embodiments relate to a unipolar carbon nanotube and a field effect transistor having the same. Other example embodiments relate to a unipolar carbon nanotube having a carrier-trapping material which transforms ambipolar nanotube characteristics into unipolar nanotube characteristics and a field effect transistor having the same.

2. Description of the Related Art

Nanotube field effect transistors are widely used for electrical applications due to the electrical properties associated with nanotube field effect transistors. Nanotube field effect transistors characteristically show ambipolar electrical characteristics. The ambipolar electrical characteristics may be undesirable when using the nanotube field effect transistors in devices.

As acknowledged in the related art, a p-type carbon nanotube field effect transistor (CNT FET) may be realized (or formed) by “V” cutting a silicon substrate under an etched region after etching a gate oxide layer. This method involves a complicated manufacturing process.

### SUMMARY OF THE INVENTION

Example embodiments relate to a unipolar carbon nanotube and a field effect transistor having the same. Other example embodiments relate to a unipolar carbon nanotube having a carrier-trapping material which transforms ambipolar nanotube characteristics into unipolar nanotube characteristics and a field effect transistor having the same.

According to example embodiments, there is provided a unipolar carbon nanotube including a carbon nanotube and a carrier-trapping material sealed in the carbon nanotube wherein the carrier-trapping material dopes the carbon nanotube.

If the carbon nanotube is a p-type carbon nanotube, then the carrier-trapping material may be halogen molecules (e.g., elements that belong to Group VII or VIIA). The halogen molecules may be bromine (Br) or iodine (I) molecules. The halogen molecules may each be formed of an odd number of halogen atoms.

If the carbon nanotube may be a n-type carbon nanotube, then the carrier-trapping material may include electron donor molecules. The electron donor molecules may be alkali metal molecules or alkaline-earth metal molecules. The electron donor molecules may be cesium (Cs) or barium (Ba) molecules.

According to other example embodiments, there is provided a unipolar field effect transistor including a source electrode and a drain electrode, a gate electrode, a first insulating layer that separates the gate electrode from the source and drain electrodes, a carbon nanotube that electrically contacts the source and drain electrodes and functions as a channel region of the field effect transistor and/or a carrier-trapping material sealed in the carbon nanotube wherein the carrier-trapping material dopes the carbon nanotube.

The field effect transistor may further include a substrate for the field effect transistor wherein the first insulating layer is formed on the substrate. The source electrode, the drain electrode and the carbon nanotube may be disposed (or positioned) on the first insulating layer. The carbon nanotube may extend between the source electrode and the drain electrode.

A second insulating layer may be disposed (or positioned) on the carbon nanotube. The gate electrode may be disposed (or positioned) on the second insulating layer.

### BRIEF DESCRIPTION OF THE DRAWINGS

Example embodiments will be more clearly understood from the following detailed description taken in conjunction with the accompanying drawings. FIGS. 1-5 represent non-limiting, example embodiments as described herein.

FIG. 1 is a diagram illustrating a cross-sectional view of a unipolar carbon nanotube field effect transistor (CNT FET) according to example embodiments;

FIG. 2 is a diagram illustrating bromine (Br) molecules sealed in carbon nanotubes (CNTs) according to example embodiments;

FIG. 3 is a graph of formation energy as a function of chirality of a CNT calculated using an Ab initio program when Br molecules and a CNT are combined according to example embodiments;

FIG. 4 is a graph of simulated partial density of state (PDOS) of a CNT as a function of energy using an Ab initio program when Br molecules are combined with the CNT according to example embodiments; and

FIG. 5 is a diagram illustrating a cross-sectional view of a unipolar CNT FET according to example embodiments.

### DETAILED DESCRIPTION OF THE INVENTION

Various example embodiments will now be described more fully with reference to the accompanying drawings in which some example embodiments are shown. In the drawings, the thicknesses of layers and regions may be exaggerated for clarity.

Detailed illustrative embodiments are disclosed herein. However, specific structural and functional details disclosed herein are merely representative for purposes of describing example embodiments. This invention may, however, may be embodied in many alternate forms and should not be construed as limited to only the example embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the scope of the example embodiments.

Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments, various aspects will be described in detail with reference to the attached drawings. However, the present invention is not limited to the example embodiments described.

Example embodiments relate to a unipolar carbon nanotube and a field effect transistor having the same. Other example embodiments relate to a unipolar carbon nanotube having a carrier-trapping material which transforms ambipolar nanotube characteristics into unipolar nanotube characteristics and a field effect transistor having the same.

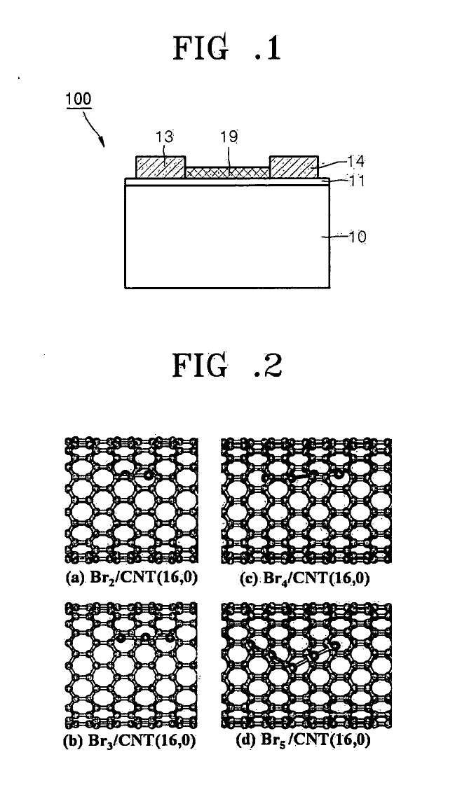

FIG. 1 is a diagram illustrating a cross-sectional view of a unipolar carbon nanotube field effect transistor (CNT FET) according to example embodiments.

Referring to FIG. 1, the unipolar CNT FET 100 may include an insulating layer 11 formed on a conductive substrate 10. The insulating layer 11 may be a gate oxide layer. The gate oxide layer may be a silicon oxide layer. If the gate oxide layer is a silicon oxide layer, then the conductive substrate 10 may be a highly doped silicon wafer.

Electrodes 13 and 14, which may disposed (or positioned) a desired distance apart from each other, may be formed on the insulating layer 11. A carbon nanotube (CNT) 19 that electrically connects the electrodes 13 and 14 may be formed between the electrodes 13 and 14. The electrodes 13 and 14 may function as a drain region and a source region, respectively. The CNT 19 may function as a channel region. The conductive substrate 10 may function as a back gate electrode.

The CNT 19 may be a single-walled CNT. Halogen molecules (e.g., bromine (Br) molecules) may be sealed in the CNT 19. The halogen molecules may be integrated in the CNT 19. The sealing (or integration) of the Br molecules may be achieved by ion showering (or implanting) of the Br atoms or by dipping the CNT in an aqueous Br solution.

FIG. 2 is a diagram illustrating Br molecules sealed in a CNT according to example embodiments.

Referring to FIG. 2, the Br molecules may be formed of 2-5 Br atoms.

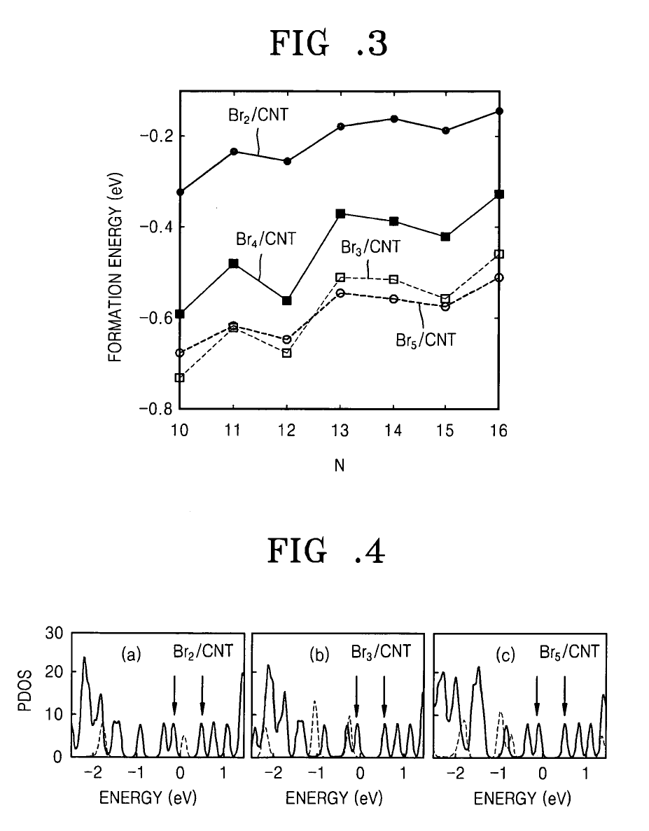

FIG. 3 is a graph of formation energy as a function of chirality of a CNT calculated using an Ab initio program when Br molecules and a CNT are combined according to example embodiments. The chirality of the CNT is plotted along the horizontal axis in terms of N from the CNT (N,0) structure (also referred to as ‘zigzag’ structure).

Referring to FIG. 3, the bonding energy of Br molecules formed of odd numbers of Br atoms (e.g., Br₃ or Br₅) in the CNT may be lower than the bonding energy of the Br molecules formed of even numbers of Br atoms (e.g., Br₂ or Br₄). The Br molecules, which may each be formed of an odd number of Br atoms (e.g., Br₃ or Br₅), may be more easily combined (or integrated) in the CNT.

FIG. 4 is a graph of simulated partial density of state (PDOS) of a CNT as a function of energy using an Ab initio program when Br molecules are combined (or integrated) with the CNT according to example embodiments. The solid line represents the PDOS of the CNT. The dotted line represents the local spin-density generated by combining the Br molecules with the CNT. The arrows in FIG. 4 indicate band gap energies of the CNT.

Referring to FIG. 4, the local spin-density generated when the Br₃ and Br₅ molecules are combined with the CNT may be significantly lower than the Fermi level. The Fermi level is the term used to describe the top of the collection of electron energy levels at absolute zero temperature. The significantly lower local spin-density state does not effect to the band energy state of the CNT.

If the CNT and the Br molecules combine, then the CNT becomes p-type because the Br molecules take (or accept) electrons from the CNT by combining (or integrating) with carbon of the CNT. Br molecules may function as a carrier-trapping material that removes (or accepts) electrons from the CNT. The combining of the Br molecules with the CNT may be characterized as strong adsorption or p-doping. Br, which function as a carrier-trapping material, may alter (or change) the CNT into a p-type unipolar CNT. As such, field effect transistor that includes the p-type unipolar CNT may be a p-type unipolar CNT FET.

If Br₂ molecules combine (or integrate) with the CNT, then a local spin-density exists between a valence band and a conducting band. The local spin-density may affect the band gap energy of the CNT. The possibility of the existence of Br molecules in the Br₂ form may be considerable low due to the formation energy between Br₂ and the CNT as indicated in FIG. 3.

In example embodiments, Br may be used as the carrier-trapping material, but the example embodiments are not limited thereto. Any halogen molecule or element from Group VII or VIIA (e.g., iodine (I) molecule) may be used as the carrier-trapping material.

An alkali metal or alkaline-earth metal (e.g., Cs or Ba) may be used as the carrier-trapping material instead of the halogen molecule. If a metal (e.g., Cs or Ba) is used as the carrier-trapping material, then the CNT becomes n-type because the metal atom provides (or donates) electrons to the CNT when this metal atom combines (or integrates) with carbon of the CNT. As such, the metal atom carrier-trapping material may be an electron donor molecule that provides (or donates) electrons to the CNT. A field effect transistor having the n-type CNT may be an n-type field effect transistor.

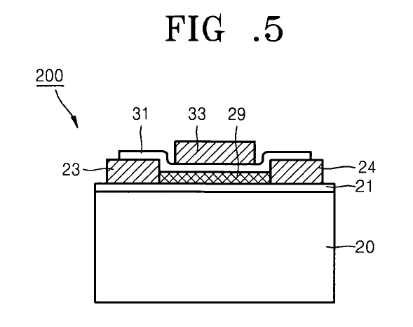

FIG. 5 is a diagram illustrating a cross-sectional view of a unipolar CNT FET according to example embodiments.

Referring to FIG. 5, the unipolar CNT FET 200 may include a first insulating layer 21 formed on a substrate 20. The substrate 20 may be conductive. The first insulating layer 21 may be a gate oxide layer. The gate oxide layer may be a silicon oxide layer. If the gate oxide layer is a silicon oxide layer, then the substrate 20 may be a highly doped silicon wafer.

Electrodes 23 and 24, which may be disposed (or positioned) a desired distance apart from each other, may be formed on the first insulating layer 21. A CNT 29 that electrically connects the two electrodes 23 and 24 may be formed between the electrodes 23, 24. A second insulating layer 31 may be formed on the CNT 29 and the electrodes 23, 24. The second insulating layer 31 may be a gate oxide layer. The gate oxide layer may be a silicon oxide layer.

A patterned gate electrode 33 may be formed above a channel region between the electrodes 23, 24 on the second insulating layer 31. The electrodes 23 and 24 may function as a drain region and a source region, respectively. The CNT 29 may function as the channel region.

The CNT 29 may be a single-walled CNT. Halogen molecules (e.g., Br molecules) may be sealed in the CNT 29. The halogen molecules may be integrated in the CNT 29. The Br molecules may be Br₃ or Br₅ molecules. The Br molecule, which functions as a carrier-trapping material, may transform the CNT 29 into a p-type unipolar CNT. As such, a field effect transistor having the CNT 29 may be a p-type unipolar CNT FET.

According to the example embodiments, an ambipolar characteristic of a CNT may be transformed into a unipolar characteristic by sealing a carrier-trapping material in the CNT. P-type and n-type CNTs and FETs may be realized (or formed) depending on the carrier-trapping material used.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A unipolar carbon nanotube, comprising:
a carbon nanotube; and
a carrier-trapping material sealed in the carbon nanotube,
wherein the carrier-trapping material dopes the carbon nanotube.

2. The unipolar carbon nanotube of claim 1, wherein the carrier-trapping material includes halogen molecules, and the carbon nanotube is a p-type carbon nanotube.

3. The unipolar carbon nanotube of claim 2, wherein the halogen molecules are bromine (Br) or iodine (I) molecules.

4. The unipolar carbon nanotube of claim 2, wherein the halogen molecules are each formed of an odd number of halogen atoms.

5. The unipolar carbon nanotube of claim 1, wherein the carrier-trapping material is formed of electron donor molecules, and the carbon nanotube is an n-type carbon nanotube.

6. The unipolar carbon nanotube of claim 5, wherein the electron donor molecules include alkali metal molecules or alkaline-earth metal molecules.

7. The unipolar carbon nanotube of claim 6, wherein the alkali metal molecules are formed of cesium (Cs) molecules.

8. The unipolar carbon nanotube of claim 6, wherein the alkaline-earth metal molecules are formed of barium (Ba) molecules.

9. The unipolar carbon nanotube of claim 1, wherein the carbon nanotube is a single-walled carbon nanotube.

10. A unipolar field effect transistor, comprising:
a source electrode and a drain electrode;
a gate electrode;
a first insulating layer that separates the gate electrode from the source and drain electrodes; and
the carbon nanotube and the carrier-trapping material according to claim 1, wherein the carbon nanotube electrically contacts the source and drain electrodes and functions as a channel region of the unipolar field effect transistor, and the carrier-trapping material is sealed in the carbon nanotube.

11. The field effect transistor of claim 10, wherein the carrier-trapping material includes halogen molecules, and the field effect transistor is a p-type field effect transistor.

12. The field effect transistor of claim 11, wherein the halogen molecules are bromine (Br) or iodine (I) molecules.

13. The field effect transistor of claim 11, wherein the halogen molecules are each formed of an odd number of halogen atoms.

14. The field effect transistor of claim 10, wherein the carrier-trapping material includes electron donor molecules, and the field effect transistor is an n-type field effect transistor.

15. The field effect transistor of claim 14, wherein the electron donor molecules are alkali metal molecules or alkaline-earth metal molecules.

16. The field effect transistor of claim 15, wherein the alkali metal molecules include cesium (Cs) molecules.

17. The field effect transistor of claim 15, wherein the alkaline-earth metal molecules include barium (Ba) molecules.

18. The field effect transistor of claim 10, further comprising a substrate, and a second insulating layer formed on the substrate, the source and drain electrodes and the carbon nanotube are positioned on the second insulating layer, and the carbon nanotube extends between the source and drain electrodes.

19. The field effect transistor of claim 18, wherein the substrate is doped and functions as a back gate.

20. The field effect transistor of claim 10, wherein the second insulating layer is positioned on the carbon nanotube, and the gate electrode is positioned on the second insulating layer.

21. The field effect transistor of claim 10, wherein the carbon nanotube is a single-walled carbon nanotube.
